(19) United States
(12) Patent Application Publication
(10) Pub. No.: US 2025/0316641 A1
(43) Pub. Date: Oct. 9, 2025

(54) STAGE FOR BONDING DIE

(71) Applicant: INNO ROBOTICS INC., Hwaseong-si (KR)

(72) Inventor: Kyu Jung CHO, Hwaseong-si (KR)

(73) Assignee: INNO ROBOTICS INC., Hwaseong-si (KR)

(21) Appl. No.: 18/931,793

(22) Filed: Oct. 30, 2024

(30) Foreign Application Priority Data
Apr. 5, 2024 (KR) 10-2024-0046338

(51) Int. Cl. H01L 23/00; H01L 21/67; H01L 21/677; H02K 9/19

(52) U.S. Cl. CPC H01L 24/74; H01L 21/67259; H01L 21/67742; H01L 21/67748; H01L 2224/74; H02K 9/19

(57) ABSTRACT

A die bonding stage disclosed herein refers to a die bonding stage for a semiconductor wafer and includes a surface plate; a single pair of bridges installed on the surface plate; and a base installed on the single pair of bridges, and the base is in a rectangular frame shape with open center by integrally combining a horizontal beam and a vertical beam in which a stator is installed on the inner side of the horizontal beam and a slider track is installed on the outer side of the horizontal beam, and includes a first mover and a second mover configured to move along the stator; and a first slider and a second slider configured to move along the slider track.

### CROSS-REFERENCE TO RELATED APPLICATION(S)

This application claims the benefit under 35 USC § 119 (a) of Korean Patent Application No. 10-2024-0046338 filed on Apr. 5, 2024 in the Korean Intellectual Property Office, the entire disclosure of which is incorporated herein by reference for all purposes.

### BACKGROUND

### 1. Field

The present invention relates to a die bonding stage device, and more particularly, to a die bonding stage that moves a wafer chip from a wafer supply location to a die bonding location on a substrate and mounts the wafer chip on the substrate.

### 2. Related Art

Very precise control is required to transfer a wafer chip to a substrate. In particular, a picker unit that transfers the wafer chip needs to move and to place the wafer chip on the substrate. Here, considering the tact time for transferring the wafer chip, the transfer needs to be completed at a very high speed.

In general, the picker unit that moves while changing its direction at a speed of 2 m/s has operating characteristics that vibration occurs inevitably. The vibration generated by the picker unit affects the entire stage.

### SUMMARY

An objective of the present invention is to provide a die bonding stage with improved precision.

Also, an objective of the present invention is to provide a die bonding stage that may cancel out vibration occurring in the die bonding stage.

Also, an objective of the present invention is to provide a die bonding stage with improved space efficiency.

A die bonding stage according to an example embodiment refers to a die bonding stage for a semiconductor wafer, and includes a surface plate; a single pair of bridges installed on the surface plate; and a base installed on the single pair of bridges, and the base is in a rectangular frame shape with open center by integrally combining a horizontal beam and a vertical beam in which a stator is installed on the inner side of the horizontal beam and a slider track is installed on the outer side of the horizontal beam, and includes a first mover and a second mover configured to move along the stator; and a first slider and a second slider configured to move along the slider track.

As an example embodiment, a picker unit configured to transfer a wafer chip may be installed below the first mover.

The die bonding stage according to an example embodiment may further include a first encoder installed on the side of the first mover; and a second encoder installed on the side of the second mover.

Also, the die bonding stage according to an example embodiment may further include a first moving portion installed below the first mover and configured to provide thrust; and a second moving portion installed below the second mover and configured to provide thrust.

As an example embodiment, the first moving portion and the second moving portion may be water-cooled linear motors that insert into the stator and have a cooling jacket through which coolant passes.

The die bonding stage according to an example embodiment may further include a bracket installed on the horizontal beam; and a cable tray is fastened on top of the bracket and installed along the horizontal beam.

As an example embodiment, when transferring, the first mover and the second mover may move in the space formed by the bracket below the cable tray.

According to a die bonding stage according to an example embodiment, it is possible to perform a precise control location of a wafer chip.

Also, it is possible to effectively cancel out vibration without expanding a space occupied by a device compared to the existing device.

The additional scope of applicability of the present invention will become apparent from the detailed description set forth herein. However, since various modifications and alterations within the spirit and scope of the present invention may be clearly understood by one of ordinary skill in the art, the detailed description and specific example embodiments such as preferred example embodiments should be understood as being given as examples only.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 is a perspective view of a die bonding stage according to an example embodiment; and

FIG. 2 is a partially enlarged view of a die bonding stage according to an example embodiment.

### DETAILED DESCRIPTION

The specific structural or functional descriptions of example embodiments according to the concept of the present invention disclosed herein are merely intended for the purpose of describing the example embodiments according to the concept of the present invention and the example embodiments according to the concept of the present invention may be implemented in various forms and are not construed as limited to the example embodiments described herein.

Although terms of “first,” “second,” and the like are used to explain various components, the components are not limited to such terms. These terms are used only to distinguish one component from another component. For example, a first component may be referred to as a second component, or similarly, the second component may be referred to as the first component without departing from the scope according to the concept of the present invention.

When it is mentioned that one component is “connected” or “accessed” to another component, it may be understood that the one component is directly connected or accessed to another component or that still other component is interposed between the two components. In addition, when it is described that one component is “directly connected” or “directly accessed” to another component, it should be understood that still other component is absent therebetween. Likewise, expressions describing relationships between components, for example, “between” and “immediately between” and “immediately adjacent to” may also be construed as described in the foregoing.

The terminology used herein is for the purpose of describing particular example embodiments only and is not to be limiting of the present invention. As used herein, the singular forms “a,” “an,” and “the” are intended to include the plural forms as well, unless the context clearly indicates otherwise. It will be further understood that the terms “comprises/includes” or “has,” when used in this specification, specify the presence of stated features, integers, stages, operations, components, parts, or combinations thereof, but do not preclude the presence or addition of one or more other features, integers, stages, operations, components, parts, or combinations thereof.

Hereinafter, example embodiments will be described in detail with reference to the accompanying drawings.

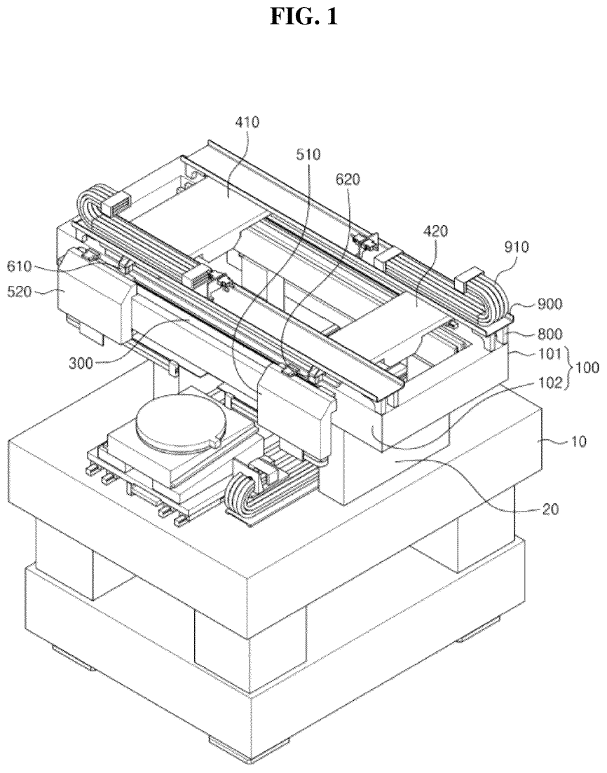

FIG. 1 is a perspective view of a die bonding stage according to an example embodiment

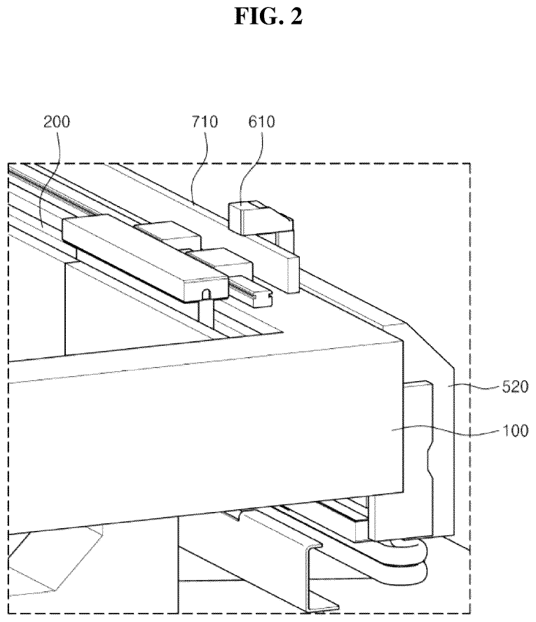

FIG. 2 is a partially enlarged view of a die bonding stage according to an example embodiment.

Referring to FIGS. 1 and 2, the die bonding stage according to an example embodiment refers to a die bonding stage for a semiconductor wafer, and includes a surface plate 10, a single pair of bridges 20 installed on the surface plate 10, and a base 100 installed on the single pair of bridges 20, and the base 100 is in a rectangular frame shape with an open center by integrally combining a horizontal beam 101 and a vertical beam 102 in which a stator 200 is installed on the inner side of the horizontal beam 101 and a slider track 300 is installed on the outer side of the horizontal beam 101, and includes a first mover 410 and a second mover 420 configured to move along the stator 200 and a first slider 510 and a second slider 520 configured to move along the slider track 300.

The surface plate 10 is a sturdy block or table of a metal with an accurate and smooth flat plate. In general, a stone surface plate formed of stone is used.

The surface plate 10 is used as a basic horizontal reference plane for precise inspection, marking (layout), and tooling setup, and is a hard and flat plate.

The single pair of bridges 20 installed on the surface plate 10 may be coupled with the same material as that of the surface plate 10, or may be integrally formed with the surface plate 10.

It is desirable that the single pair of bridges 20 is coupled to the surface plate 10 at locations spaced apart from each other enough to form a space in which the wafer may be introduced between the bridges 20 and processed.

The base 100 is installed on the single pair of bridges 20. The base 100 is in the rectangular frame shape with the open center, allowing the wafer to be processed in an upper portion of the space between the bridges 20 as described above.

The base 100 forms a rectangular frame through integral combination of the horizontal beam 101 and the vertical beam 102. As shown in FIG. 1, the vertical beam 102 may be formed to be longer than the horizontal beam 101, and may also have the same length as that of the horizontal beam 101 to form a square frame. However, it corresponds to simple design modification according to process characteristics.

The base 100 may also have an integrated structure made of a granite material and the bridges 20 are located below both ends of the horizontal beam 101 of the base 100, and the base 100 is accommodated on the top of the bridges 20.

The stator 200 is installed on the inner side of the horizontal beam 101 of the base 100. The stator 200 has magnets of different polarities arranged in a line, and the stator 200 includes a first moving portion 710 and a second moving portion (not shown) in which a coil is installed. Here, when current is applied to the coil, the first mover 410 and the second mover 420, described below, move.

Also, the slider track 300 is installed on the outer side of the horizontal beam 101. The slider track 300 allows the first slider 510 and the second slider 520 to move on both sides.

Similar to the aforementioned stator 200, the slider track 300 has magnets of different polarities arranged in a line. The first mover 410 may be made of SIC material, but is not limited thereto. A picker unit configured to transfer a wafer chip may be installed below the slider track 300. Also, a shooting module for aligning a location of the first mover 410 and a location of the picker unit may be installed.

Similar to the first mover 410, the second mover 420 may be made of SIC material, but is not limited thereto. In a standby state, the second mover 420 is located in an opposite direction to the first mover 410. A vision camera is installed below the second mover 420, and the second mover 420 photographs the wafer chip and computes a location of the wafer chip to be moved by the picker unit.

The first mover 410 moves to an upper portion in which the wafer is present and is aligned, and verifies a location of the wafer chip to be coupled to the substrate in a video captured through the vision camera installed in the second mover 420.

The picker unit picks the wafer chip, and the first mover 410 transfers the wafer chip onto the substrate.

A first encoder 610 is installed on the side of the first mover 410 to measure a location of the first mover 410, and a second encoder 620 is installed on the side of the second mover 420 to measure a location of the second mover 420.

As described above, the coil is installed in the first moving portion 710 installed below the first mover 410 and configured to provide thrust, and the thrust is provided by current that is applied to the coil.

Similar to the first moving portion 710, the coil is installed in the second moving portion (not shown) installed below the second mover 420 and configured to provide thrust, and the thrust is provided by current that is applied to the coil.

The first moving portion 710 and the second moving portion (not shown) insert into the stator 200 and transfer the first mover 410 and the second mover 420 with the thrust generated by electromagnetic force. In this process, heat is generated, which may cause a problem in transferring the first mover 410 and the second mover 420.

Therefore, in the die bonding stage according to an example embodiment, a cooling jacket through which coolant passes is installed in the first moving portion 710 and the second moving portion (not shown). The cooling jacket may attach thin carbon fiber reinforced plastic (CFRP) to generate a manifold structure that allows coolant to pass through.

That is, the CFRP is a plastic composite material that uses carbon fiber as a reinforcement material, and is suitable as a material for the first moving portion 710 and the second moving portion (not shown) due to a lightweight structural material. Also, due to lower thermal conductivity compared to metals such as glass fiber reinforced plastic (GFRP), the CFRP is a suitable material to apply to the first moving portion 710 and the second moving portion (not shown) built with the coil of a linear motor that generates heat.

The first slider 510 and the second slider 520 move along the slider track 300 installed on the outer side of the horizontal beam 101 of the base 100.

As shown in FIGS. 1 and 2, the first mover 410 moves along the stator 200 in response to the current applied to the first moving portion 710. Here, the tact time of the first mover 410 is 2 m/s to 3 m/s and the first mover 410 generally moves at a very high speed. The vibration occurring in this process is transmitted as is to the picker unit (not shown) and the base 100 that deliver the wafer chip, and causes a problem in chip packaging.

Therefore, the first slider 510 that may cancel out the vibration caused by movement of the first mover 410 is formed. For example, if the first mover 410 moves toward the second mover 420, the first slider 510 moves in the direction of the first mover 410 along the slider track 300 and cancels out the vibration.

Also, if the second mover 420 moves toward the first mover 410, the second slider 520 moves in the direction of the second mover 420 along the slider track 300 and cancels out the vibration.

The first mover 410 and the first slider 510 move in opposite directions, and the second mover 420 and the second slider 520 also move in opposite directions, canceling out the vibration that may occur in instrument.

The first slider 510 is symmetrically installed to move along the slider track 300 installed on each of both outer side surfaces of the horizontal beam 101. Similar to the first slider 510, the second slider 520 is symmetrically installed to move along the slider track 300 installed on each of both outer side surfaces of the horizontal beam 101.

As shown in FIG. 1, in the die bonding stage according to an example embodiment, a bracket 800 is installed on the horizontal beam 101. In more detail, the brackets 800 are installed at four corners at which the horizontal beams 101 and the vertical beams 102 meet, respectively. A cable tray 900 installed along the horizontal beam 101 is located on top of the bracket 800.

The cable tray 900 includes a cable 910 in which a power line for power supply and a coolant cable for supplying coolant supplied to the first moving portion 710 and the second moving portion (not shown) are combined.

When transferring, the first mover 410 and the second mover 420 moves in the space formed by the bracket 800 below the cable tray 900.

That is, by locating the cable 910 to be above the first mover 410 and the second mover 420 through the cable tray 900, interference caused by the cable 910 may be minimized when the first mover 410 and the second mover 420 move. Also, due to a stack structure, it is possible to improve space utilization and also to minimize stress applied to mechanism.

Accordingly, in the die bonding stage according to an example embodiment, the slider track 300 is installed on the outer side of the horizontal beam 101 of the base 100 and accordingly, the first slider 510 and the second slider 520 that move along the slider track 300 cancel out the vibration caused by movement of the first mover 410 and second mover 420 that actually transfer the wafer chip.

Also, provided is the die bonding stage that guarantees space utilization by being designed in a structure in which the cable 910 that supplies power is installed above the base 100, and more particularly, installed on the upper side of the first mover 410 and the second mover 420, minimizing interference with the first mover 410 and the second mover 420 and not affecting the size of mechanism.

Various modifications may be made to the example embodiments according to the concept of the present invention and thus, the example embodiments are illustrated in the drawings and described in detail through the present specification. However, it should be understood that the example embodiments according to the concept of the present invention are not construed as limited to specific implementations and should be understood to include all changes, equivalents, and replacements within the idea and the technical scope of the present invention.

What is claimed is:

1. A die bonding stage for a semiconductor wafer, the die bonding state comprising:
a surface plate;
a single pair of bridges installed on the surface plate; and
a base installed on the single pair of bridges,
wherein the base is in a rectangular frame shape with open center by integrally combining a horizontal beam and a vertical beam in which a stator is installed on the inner side of the horizontal beam and a slider track is installed on the outer side of the horizontal beam, and comprises:
a first mover and a second mover configured to move along the stator; and
a first slider and a second slider configured to move along the slider track.

2. The die bonding stage of claim 1, wherein a picker unit configured to transfer a wafer chip is installed below the first mover.

3. The die bonding stage of claim 1, further comprising:
a first encoder installed on the side of the first mover; and
a second encoder installed on the side of the second mover.

4. The die bonding stage of claim 1, further comprising:
a first moving portion installed below the first mover and configured to provide thrust; and
a second moving portion installed below the second mover and configured to provide thrust.

5. The die bonding stage of claim 4, wherein the first moving portion and the second moving portion are water-cooled linear motors that insert into the stator and have a cooling jacket through which coolant passes.

6. The die bonding stage of claim 1, further comprising:
a bracket installed on the horizontal beam; and
a cable tray is fastened on top of the bracket and installed along the horizontal beam.

7. The die bonding stage of claim 6, wherein, when transferring, the first mover and the second mover move in the space formed by the bracket below the cable tray.
